(19) United States
(12) Patent Application Publication
(10) Pub. No.: US 2026/0301646 A1
(43) Pub. Date: Oct. 1, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yonglin Guo, Beijing (CN); Gukhwan Song, Beijing (CN); Youngjang Lee, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/992,246

(22) PCT Filed: Aug. 13, 2024
(86) PCT No.: PCT/CN2024/111595

§ 371 Date: Jan. 8, 2025

(30) Foreign Application Priority Data
Sep. 25, 2023 (CN) 202311243257.5

(51) Int. Cl. G09G 3/32

(52) U.S. Cl. CPC G09G 3/32; G09G 2300/0426; G09G 2310/0267; G09G 2320/0209; G09G 2320/0233; G09G 2320/045

(57) ABSTRACT

This disclosure provides a display substrate and a display device. In the display substrate, a display region is between a first bezel region and a second bezel region of a peripheral region and includes a first display region and a second display region, the first display region includes a first sub-region and a second sub-region, and at least a part of the second sub-region is located in the same row as the second display region along a first direction; at least a part of a first target scanning line in the display substrate is in the second sub-region, and in the first target scanning line, a first end of a first scanning layer is coupled to a first end of a second scanning layer, and a corresponding first scanning driving unit, a second end of the first scanning layer is coupled to a second end of the second scanning layer.

### CROSS-REFERENCE TO RELATED APPLICATION

The present application claims a priority to the Chinese patent application No. 202311243257.5 filed in China on Sep. 25, 2023, a disclosure of which is incorporated herein by reference in its entirety.

### TECHNICAL FIELD

The present disclosure relates to the field of display technology, in particular to a display substrate and a display device.

### BACKGROUND

Low Temperature Polycrystalline Oxide (LTPO) transistors are highly favored for their features such as low power consumption and improved image retention. However, due to the poor photostability of LTPO transistors, common designs of LTPO transistors require both a top gate and a bottom gate to ensure the photostability of the device.

With the continuous development of display technology, narrow bezel has become the mainstream trend of display product development. Under this development trend, single-sided driving technology using Gate On Array (GOA) is widely used. Display products using the driving technology impose higher requirements on the design of the top gate and the bottom gate of the device, and will provide scanning signals to the top gate and the bottom gate through two layers of scanning lines. However, conventional display products that incorporate GOA single-sided driving technology and LTPO transistors have defects such as abnormal display and Hole Mura.

### SUMMARY

The purpose of the present disclosure is to provide a display substrate and a display device.

In order to achieve the above purpose, the present disclosure provides the following technical solutions.

A first aspect of the present disclosure provides a display substrate, including: a display region and a peripheral region located at a periphery of the display region; the peripheral region including a first bezel region and a second bezel region arranged opposite to each other along a first direction; the display region is located between the first bezel region and the second bezel region, the display region includes a first display region and a second display region, the first display region includes a first sub-region and a second sub-region, at least a part of the second sub-region is located in a same row as the second display region along the first direction, and the first sub-region and the second display region are located in different rows along the first direction;
the display substrate further include: a plurality of first scanning driving units and a plurality of first scanning lines; the first scanning driving units are located in the first bezel region; each of the first scanning lines including a first scanning layer and a second scanning layer;
the plurality of first scanning lines include a plurality of first target scanning lines, at least a part of each of the first target scanning lines is located in the second sub-region, and in each of the first target scanning lines, a first end of the first scanning layer is coupled to a first end of the second scanning layer and is coupled to a corresponding first scanning driving unit of the first scanning driving units, a second end of the first scanning layer is coupled to a second end of the second scanning layer, the first ends are located in the first bezel region, and the second ends are located in the second bezel region.

Optionally, the plurality of first scanning lines include a plurality of second target scanning lines, at least a part of each of the second target scanning lines is located in the first sub-region, and in each of the second target scanning lines, a first end of the first scanning layer is coupled to a first end of the second scanning layer and is coupled to a corresponding first scanning driving unit of the first scanning driving units, a second end of the first scanning layer is coupled to a second end of the second scanning layer, the first ends are located in the first bezel region, and the second ends are located in the second bezel region.

Optionally, in each of the first target scanning lines, the first scanning layer includes a first scanning pattern and a second scanning pattern, and the second scanning layer includes a third scanning pattern and a fourth scanning pattern; the second display region is located between the first scanning pattern and the second scanning pattern, and the second display region is located between the third scanning pattern and the fourth scanning pattern;
a first end of the first scanning pattern is the first end of the first scanning layer, a second end of the second scanning pattern is the second end of the first scanning layer, a first end of the third scanning pattern is the first end of the second scanning layer, and a second end of the fourth scanning pattern is the second end of the second scanning layer; the second end of the first scanning pattern is coupled to the second end of the third scanning pattern, and the first end of the second scanning pattern is coupled to the first end of the fourth scanning pattern.

Optionally, the first target scanning line further includes a circling wire portion, the circling wire portion is located in the second sub-region, and at least a part of the circling wire portion is arranged around the second display region; the circling wire portion is coupled to the second end of the first scanning pattern, the first end of the second scanning pattern, the second end of the third scanning pattern and the first end of the fourth scanning pattern.

Optionally, the circling wire portions coupled to the adjacent first scanning patterns are independent of each other; or, the adjacent first scanning patterns are coupled to the same circling wire portion.

Optionally, the plurality of first scanning lines are divided into a plurality of scanning groups, each of the scanning groups includes two adjacent first scanning lines of the plurality of first scanning lines; the display substrate includes a plurality of first adapter portions, each of the first adapter portions is coupled to the first ends of the first scanning layers and the first ends of the second scanning layers in the corresponding scanning group, and a corresponding first scanning driving unit of the first scanning driving units.

Optionally, the display substrate includes a plurality of third adapter portions; each of the third adapter portions is coupled to the second end of the first scanning layer and the second end of the second scanning layer in a corresponding first scanning line of the first scanning lines.

Optionally, the third adapter portions coupled to the first scanning lines in each of the scanning groups are coupled to each other.

Optionally, the display substrate includes a first gate metal layer, a second gate metal layer, a third gate metal layer, a first source-drain metal layer, and a second source-drain metal layer that are sequentially stacked on a base substrate of the display substrate in a direction away from the base substrate;
at least a part of each of the first adapter portions is arranged in the same layer and is made of the same material as the first gate metal layer, the second gate metal layer, the third gate metal layer, the first source-drain metal layer or the second source-drain metal layer;
at least a part of each of the third adapter portions is arranged in the same layer and is made of the same material as the first gate metal layer, the second gate metal layer, the first source-drain metal layer or the second source-drain metal layer.

Optionally, the greater a length of the circling wire portion is, the less a load of the third adapter portion is set to be.

Optionally, in the same first scanning line, an orthographic projection of the first end of the first scanning layer on the base substrate of the display substrate has an overlapping region with an orthographic projection of the first end of the second scanning layer on the base substrate, and the first end of the first scanning layer and the first end of the second scanning layer are coupled through a via hole in the overlapping region; and/or,
in the same first scanning line, an orthographic projection of the second end of the first scanning layer on the base substrate has an overlapping region with an orthographic projection of the second end of the second scanning layer on the base substrate, and the first end of the first scanning layer and the first end of the second scanning layer are coupled through a via hole in the overlapping region.

Optionally, the display substrate includes a plurality of sub-pixels, each of the sub-pixels includes a sub-pixel driving circuit, the sub-pixel driving circuit includes a driving transistor and a compensation transistor, a gate electrode of the compensation transistor is coupled to the first scanning layer and the second scanning layer in a corresponding first scanning line of the first scanning lines, a first electrode of the compensation transistor is coupled to a second electrode of the driving transistor, and a second electrode of the compensation transistor is coupled to a gate electrode of the driving transistor.

Optionally, the display substrate includes a first gate metal layer, a second gate metal layer, a third gate metal layer, a first source-drain metal layer, and a second source-drain metal layer that are sequentially stacked on the base substrate of the display substrate in a direction away from the base substrate;
the circling wire portion is arranged in the same layer and is made of the same material as the first gate metal layer, the second gate metal layer, the third gate metal layer, the first source-drain metal layer or the second source-drain metal layer.

Optionally, the circling wire portions included in two adjacent first target scanning lines are arranged in the same layer or are arranged in different layers.

Optionally, the display substrate further includes a plurality of second scanning lines, a plurality of light-emitting control signal lines, a plurality of first reset signal lines and a plurality of second reset signal lines;
an orthographic projection of the circling wire portion on the base substrate of the display substrate at least partially overlaps with an orthographic projection of at least one signal line among the second scanning lines, the light-emitting control signal lines, the first reset signal lines and the second reset signal lines on the base substrate; the at least one signal line and the circling wire portion are arranged in different layers.

Optionally, the display substrate includes a plurality of sub-pixels, and each of the sub-pixels includes a sub-pixel driving circuit, and
the first scanning layer and the second scanning layer of the same first target scanning line are coupled through at least one fourth adapter portion.

Optionally, at least a part of the fourth adapter portion is located in a layout region of the sub-pixel driving circuit, or, at least a part of the fourth adapter portion is located between layout regions of adjacent sub-pixel driving circuits.

Optionally, the first scanning line including at least two fourth adapter portions, at least one of the fourth adapter portions is located between the first bezel region and the second display region, and at least one of the fourth adapter portions is located between the second bezel region and the second display region.

Based on the technical solution of the display substrate, a second aspect of the present disclosure provides a display device including the aforementioned display substrate.

### BRIEF DESCRIPTION OF THE DRAWINGS

The drawings described herein are used for providing a further understanding of the present disclosure and constitute a part of the present disclosure. The illustrative embodiments of the present disclosure and the descriptions are used to explain the present disclosure and do not constitute an undue limitation on the present disclosure.

FIG. 1 is a schematic diagram of a circuit structure of a sub-pixel driving circuit according to an embodiment of the present disclosure;

FIG. 2 is a schematic cross-sectional diagram showing film layers in a display substrate according to an embodiment of the present disclosure;

FIG. 3 is a first layout diagram of a display substrate according to an embodiment of the present disclosure;

FIG. 4 is a layout diagram showing a first scanning line entering a first display region from a first bezel region according to an embodiment of the present disclosure;

FIG. 5 is a first layout diagram of a circling wire portion of a first scanning line according to an embodiment of the present disclosure;

FIG. 6 is a schematic diagram showing the distribution of various regions in a display region according to an embodiment of the present disclosure;

FIG. 7 is a layout diagram showing a first scanning line entering a second bezel region from a first display region according to an embodiment of the present disclosure;

FIG. 8 is a second layout diagram of a circling wire portion of a first scanning line according to an embodiment of the present disclosure;

FIG. 9 is an enlarged schematic diagram of the circling wire portion of the first scanning line corresponding to the position shown in FIG. 8;

FIG. 10 is an enlarged schematic diagram of a circling wire portion of a first scanning line corresponding to a position symmetrical to the position shown in FIG. 8;

FIG. 11 is a schematic diagram of an entire circling wire of a first scanning line according to an embodiment of the present disclosure;

FIG. 12 is a second layout diagram of a display substrate according to an embodiment of the present disclosure;

FIG. 13 is a third layout diagram of a display substrate according to an embodiment of the present disclosure;

FIG. 14 is a layout diagram of the first scanning line in a second sub-region according to an embodiment of the present disclosure;

FIG. 15 is a fourth layout diagram of a display substrate according to an embodiment of the present disclosure.

### DETAILED DESCRIPTION

In order to further illustrate the display substrate and the display device provided in the embodiments of the present disclosure, the following provides a detailed description in conjunction with the accompanying drawings.

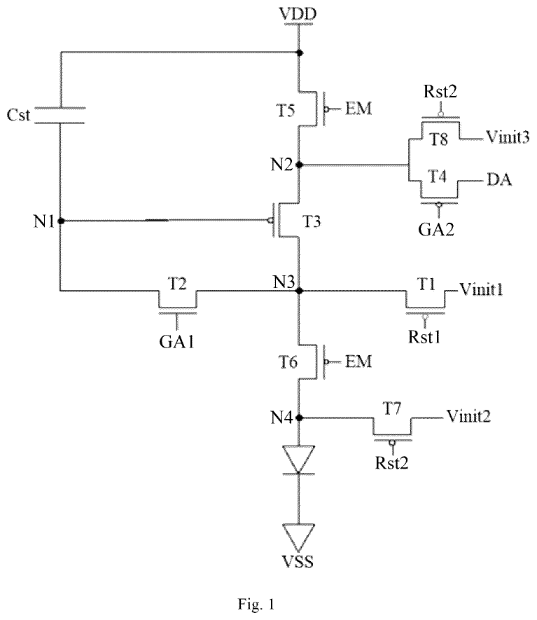

As shown in FIG. 1, the present disclosure provides a display substrate including a plurality of sub-pixels, each of the sub-pixels includes a sub-pixel driving circuit; the display substrate further includes a plurality of power lines VDD, a plurality of light-emitting control signal lines EM, a plurality of first scanning lines GA1, a plurality of second scanning lines GA2, a plurality of first reset signal lines Rstl, a plurality of second reset signal lines Rst2, a plurality of first initialization signal lines Vinit1, a plurality of second initialization signal lines Vinit2, a plurality of third initialization signal lines Vinit3, and a plurality of data lines DA.

Exemplarily, the sub-pixel driving circuit adopts an 8T1C (i.e., 8 transistors and 1 storage capacitor) circuit structure.

As shown in FIG. 1, exemplarily, the sub-pixel driving circuit includes a first reset transistor T1, a compensation transistor T2, a driving transistor T3, a data writing transistor T4, a second reset transistor T7, a power control transistor T5, a light-emitting control transistor T6, a node control transistor T8 and a storage capacitor Cst.

A gate electrode of the first reset transistor T1 is coupled to the corresponding first reset signal line Rst1, a first electrode of the first reset transistor T1 is coupled to the corresponding first initialization signal line Vinit1, and a second electrode of the first reset transistor T1 is coupled to a second electrode (i.e., the node N3) of the driving transistor T3.

A gate electrode of the compensation transistor T2 is coupled to the corresponding first scanning line GA1, a first electrode of the compensation transistor T2 is coupled to a second electrode of the driving transistor T3, and a second electrode of the compensation transistor T2 is coupled to a gate electrode (i.e., the node N1) of the driving transistor T3.

A gate electrode of the data writing transistor T4 is coupled to the corresponding second scanning line GA2, a first electrode of the data writing transistor T4 is coupled to the corresponding data line DA, and a second electrode of the data writing transistor T4 is coupled to a first electrode (i.e., the node N2) of the driving transistor T3.

A gate electrode of the power control transistor T5 is coupled to the corresponding light-emitting control signal line EM, a first electrode of the power control transistor T5 is coupled to the corresponding power line VDD, and a second electrode of the power control transistor T5 is coupled to the first electrode of the driving transistor T3.

A gate electrode of the light-emitting control transistor T6 is coupled to the corresponding light-emitting control signal line EM, a first electrode of the light-emitting control transistor T6 is coupled to the second electrode of the driving transistor T3, a second electrode of the light-emitting control transistor T6 is coupled to the anode (i.e., the node N4) of the corresponding light-emitting element, and the cathode of the light-emitting element receives a negative power signal VSS.

A gate electrode of the second reset transistor T7 is coupled to the corresponding second reset signal line Rst2, a first electrode of the second reset transistor T7 is coupled to the corresponding second initialization signal line Vinit2, and a second electrode of the second reset transistor T7 is coupled to the anode of the corresponding light-emitting element.

A gate electrode of the node control transistor T8 is coupled to the corresponding second reset signal line Rst2, a first electrode of the node control transistor T8 is coupled to the corresponding third reset signal line Vinit3, and a second electrode of the node control transistor T8 is coupled to the first electrode of the driving transistor T3.

A first plate of the storage capacitor Cst is coupled to the gate electrode of the driving transistor T3, and a second plate of the storage capacitor Cst is coupled to the corresponding power line VDD.

Exemplarily, the first reset transistor T1, the driving transistor T3, the data writing transistor T4, the power control transistor T5, the light emission control transistor T6, the second reset transistor T7, and the node control transistor T8 are all LTPS transistors, and the compensation transistor T2 is an LTPO transistor.

Exemplarily, the display substrate includes a plurality of sub-pixels, and the plurality of sub-pixels include a plurality of sub-pixel driving circuits distributed in an array. The plurality of sub-pixel driving circuits are divided into a plurality of rows of sub-pixel driving circuits and a plurality of columns of sub-pixel driving circuits. The plurality of rows of sub-pixel driving circuits are arranged along a second direction, and each row of sub-pixel driving circuits includes a plurality of sub-pixel driving circuits arranged along a first direction. The plurality of columns of sub-pixel driving circuits are arranged along the first direction, and each column of sub-pixel driving circuits includes a plurality of sub-pixel driving circuits arranged along the second direction. Exemplarily, the first direction and the second direction intersect. For example, the first direction includes a transversal direction, and the second direction includes a longitudinal direction.

Exemplarily, the sub-pixel includes a sub-pixel driving circuit and a light-emitting element. The sub-pixel driving circuit is coupled to an anode of the light-emitting element and is used for providing a driving signal to the light-emitting element to drive the light-emitting element to emit light.

Exemplarily, the plurality of rows of sub-pixel driving circuits are divided into a plurality of groups of driving circuit rows, each group of driving circuit rows includes two adjacent rows of sub-pixel driving circuits, and the two adjacent rows of sub-pixel driving circuits include one odd-numbered row of sub-pixel driving circuits and one even-numbered row of sub-pixel driving circuits.

The display substrate further includes a plurality of gate driving circuits, and the plurality of gate driving circuits include: a first scanning driving circuit, a second scanning driving circuit, a first reset driving circuit, a second reset driving circuit and a light-emitting control driving circuit.

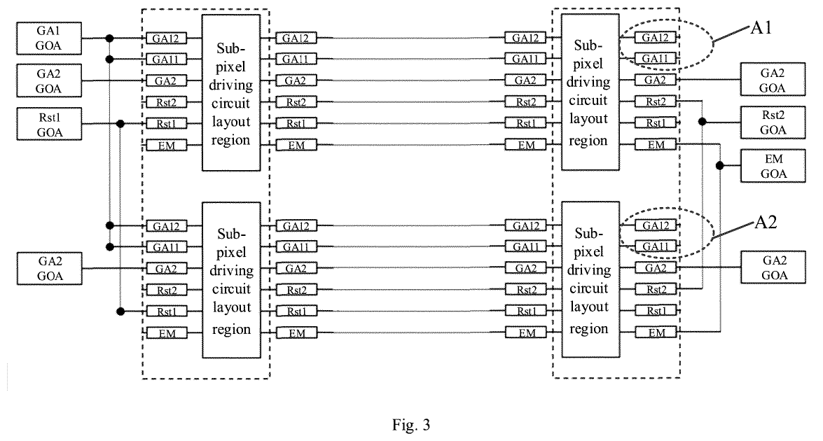

As shown in FIG. 3, the first scanning driving circuit includes a plurality of first scanning driving units GA1 GOA. The second scanning driving circuit includes a plurality of second scanning driving units GA2 GOA. The first reset driving circuit includes a plurality of first reset driving units Rst1 GOA. The second reset driving circuit includes a plurality of second reset driving units Rst2 GOA. The light-emitting control driving circuit includes a plurality of light-emitting control driving units EM GOA.

Exemplarily, the first scanning driving circuit is located in the first bezel region of the display substrate. The plurality of first scanning driving units GA1 GOA are in a one-to-one correspondence with the plurality of groups of driving circuit rows, and the first scanning driving unit GA1 GOA is coupled to two first scanning lines GA1 coupled to two rows of sub-pixel driving circuits in a corresponding group of driving circuit rows.

Exemplarily, the second scanning driving circuit is located in the first bezel region and the second bezel region of the display substrate. The second scanning driving circuit located in the first bezel region includes a plurality of second scanning driving units GA2 GOA. The second scanning driving circuit located in the second bezel region includes a plurality of second scanning driving units GA2 GOA. The first end of the second scanning line coupled to each row of sub-pixel driving circuits is coupled to the corresponding second scanning driving unit GA2 GOA located in the first bezel region. The second end of the second scanning line coupled to each row of sub-pixel driving circuits is coupled to the corresponding second scanning driving unit GA2 GOA located in the second bezel region.

Exemplarily, the first reset driving circuit is located in the first bezel region of the display substrate. The plurality of first reset driving units Rst1 GOA are in a one-to-one correspondence with the plurality of groups of driving circuit rows, and the first reset driving unit Rst1 GOA is coupled to two first reset signal lines Rst1 coupled to two rows of sub-pixel driving circuits in a corresponding group of driving circuit rows. The two first reset signal lines Rst1 coupled to two rows of sub-pixel driving circuits in a group of driving circuit rows may be coupled or uncoupled at one end away from the first reset driving unit Rst1 GOA.

Exemplarily, the second reset driving circuit is located in the second bezel region of the display substrate. The plurality of second reset driving units Rst2 GOA are in a one-to-one correspondence with the plurality of groups of driving circuit rows, and the second reset driving unit Rst2 GOA is coupled to two second reset signal lines Rst2 coupled to two rows of sub-pixel driving circuits in a corresponding group of driving circuit rows. The two second reset signal lines Rst2 coupled to two rows of sub-pixel driving circuits in a group of driving circuit rows may be coupled or uncoupled at one end away from the second reset driving unit Rst2 GOA.

Exemplarily, the light-emitting control driving circuit is located in the second bezel region of the display substrate. The plurality of light-emitting control driving units EM GOA are in a one-to-one correspondence with the plurality of groups of driving circuit rows, and the light-emitting control driving unit EM GOA is coupled to two light-emitting control signal lines EM coupled to two rows of sub-pixel driving circuits in a corresponding group of driving circuit rows. The two light-emitting control signal lines EM coupled to two rows of sub-pixel driving circuits in a group of driving circuit rows may be coupled or uncoupled at one end away from the light-emitting control driving unit EM GOA.

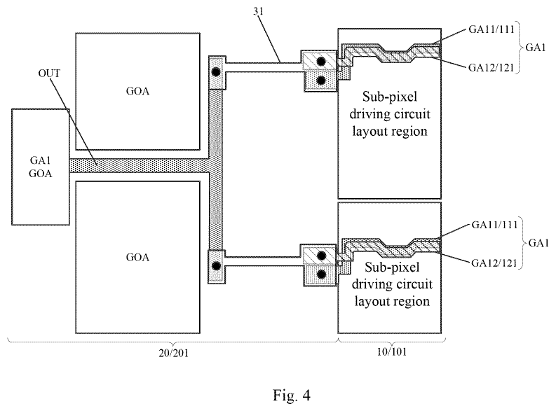

As shown in FIG. 4 and FIG. 6, exemplarily, the display substrate includes a display region 10 and a peripheral region 20 located at a periphery of the display region 10, wherein the display region includes a first display region 101 and a second display region 102, wherein the first display region at least partially surrounds the second display region; the second display region is also called a hole region, which can be used for accommodating a camera, a sensor, etc., but is not limited thereto. The second display region is not used for display, but dummy sub-pixels can be made in the region to ensure the uniformity of the display substrate.

As shown in FIG. 6, the first display region 101 includes a first sub-region 1011 and a second sub-region 1012, at least a part of the second sub-region 1012 is located in the same row as the second display region 102 along the first direction, and the first sub-region 1011 and the second display region 1012 are located in different rows along the first direction.

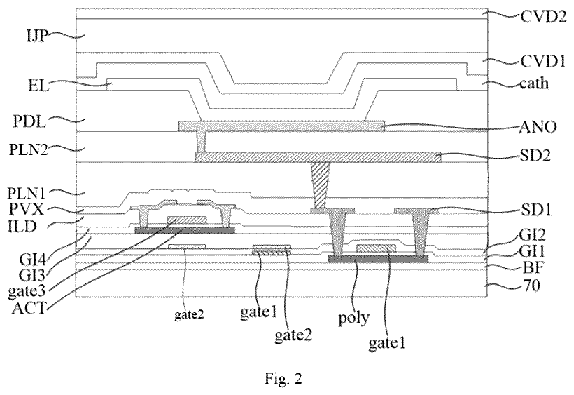

As shown in FIG. 2, exemplarily, the display substrate includes a buffer layer BF, a polysilicon active layer poly, a first gate insulating layer GI1, a first gate metal layer gate1, a second gate insulating layer GI2, a second gate metal layer gate2, a third gate insulating layer GI3, an oxide active layer ACT, a fourth gate insulating layer GI4, a third gate metal layer gate3, an interlayer insulating layer ILD, a first source-drain metal layer SD1, a first planarization layer PLN1, a second source-drain metal layer SD2, a second planarization layer PLN2, an anode layer ANO, a pixel defining layer PDL, a light-emitting functional layer EL, a cathode layer cath, a first inorganic encapsulation layer CVD1, an organic encapsulation layer IJP, and a second inorganic encapsulation layer CVD2, which are sequentially stacked in a direction away from the base substrate 70. The display substrate may also be provided with a passivation layer PVX according to actual needs. The passivation layer PVX may be located between the first source-drain metal layer SD1 and the first planarization layer PLN1, or may be located between the first planarization layer PLN1 and the second source-drain metal layer SD2.

Exemplarily, the first scanning line includes a first scanning layer and a second scanning layer, the first scanning layer and the second gate metal layer are arranged in the same layer and is made of the same material, and the second scanning layer and the third gate metal layer are arranged in the same layer and is made of the same material.

As shown in FIG. 4, the output end OUT of the first scanning driving unit GA1 GOA is divided, i.e., divided into two ends, before entering the display region 10 from the peripheral region 20, and each end is coupled to the first scanning line GA1 coupled to the corresponding row of sub-pixel driving circuits through a first adapter portion 31 made of the first source-drain metal layer. The first scanning line GA1 includes a first scanning layer GA11 and a second scanning layer GA12, and the first adapter portion 31 is coupled to the corresponding first scanning layer GA11 and the corresponding second scanning layer GA12. It should be noted that the black dots in FIG. 4 represent via holes.

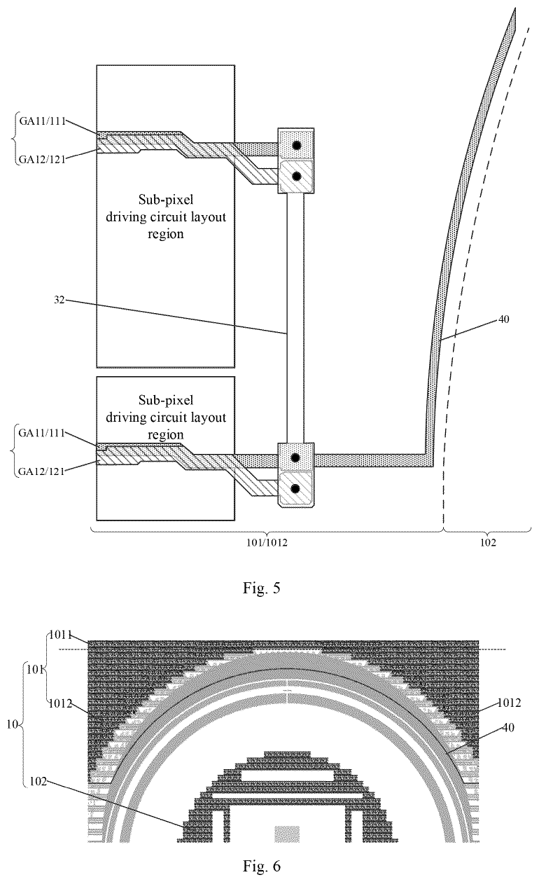

As shown in FIG. 5 and FIG. 6, near the second display region 102, in the second sub-region 1012, one end of the first scanning layer GA11 and one end of the second scanning layer GA22 that are included in the first scanning line GA1 are coupled, and two first scanning lines GA1 coupled to two rows of sub-pixel driving circuits in the same group of driving circuit rows are coupled through a second adapter portion 32. In order to reduce the bezel width at the second display region 102, the two first scanning lines GA1 coupled to two rows of sub-pixel driving circuits in the same group of driving circuit rows are coupled through the second adapter portion 32 and then circle around the second display region 102 through one circling wire portion 40. It should be noted that the black dots in FIG. 5 represent via holes.

As shown in FIG. 3, in the display substrate of the aforementioned structure, in the first scanning layer GA11 and the second scanning layer GA12 of the same first scanning line GA1, an end of the first scanning layer GA11 close to the second bezel region and an end of the second scanning layer GA12 close to the second bezel region are independent of each other, such as the portion A1 and portion A2 in FIG. 3.

The aforementioned problems, such as abnormal display and Hole Mura, of the display substrate compatible with GOA single-sided driving technology and LTPO transistor are specifically discussed as follows.

As shown in FIGS. 3 to 6, the display substrate adopts the following structure: the display substrate adopts the GOA single-sided driving technology, and at one end of the first scanning line GA1 away from the first scanning driving unit GA1 GOA, the end of the first scanning layer GA11 and the end of the second scanning layer GA12 are independent of each other; in the second sub-region 1012, before circling in the first display region 101, an end of the first scanning layer GA11 and an end of the second scanning layer GA22 included in the first scanning line GA1 are coupled, and two first scanning lines GA1 coupled to two rows of sub-pixel driving circuits in the same group of driving circuit rows are coupled through the second adapter portion 32, and then circle around the second display region 102 through one circling wire portion.

On the one hand: for the display substrate of the foregoing structure, when the second scanning line GA2 controls the data writing transistor T4 to be turned on and the data signal transmitted by the data line DA is sequentially written into the node N2, the node N3 and the node N1, the potential of the first scanning signal transmitted on the first scanning layer GA11 and the second scanning layer GA12 is pulled up by the parasitic capacitance formed between the scanning layers and the nodes N1, N2 and N3, and the magnitude by which the potential of the first scanning signal transmitted by the first scanning layer GA11 is pulled up is different from the magnitude by which the potential of the second scanning layer GA12 is pulled up, and this pull-up will slowly subside during the stage of writing data signals.

In the second sub-region 1012, near the second display region 102, the first scanning layer GA11 and the second scanning layer GA12 are coupled, and two adjacent first scanning lines GA1 circle around the second display region 102 through one circling wire portion, this arrangement will make the magnitude by which the potential of the first scanning signal transmitted by the first scanning layer GA11 is pulled up and the magnitude by which the potential of the second scanning layer GA12 is pulled up to average out near the second display region 102.

However, in other regions of the first display region 101 than the region near the second display region 102, the first scanning layer GA11 and the second scanning layer GA12 are short-circuited together at their ends before entering the first display region 101 from the peripheral region 20, and the end of the first scanning layer GA11 and the end of the second scanning layer GA12 close to the second side bezel are independent of each other. In this way, the magnitude by which the potential of the first scanning signal transmitted by the first scanning layer GA11 and the second scanning layer GA12 is pulled up in the first sub-region 1011 is different from that in the second sub-region 1012, and the electrical potential restores slower, which makes the first scanning signals received by the compensation transistors T2 in the first sub-region 1011 to be different from the first scanning signals received by the compensation transistors T2 in the second sub-region 1012, resulting in different states of the compensation transistors T2, and ultimately making the nodes N1 different from each other.

In more detail, at the moment when the second scanning line GA2 controls the data writing transistor T4 to turn off, under the coupling effect of the N1 node, the N2 node, and the N3 node, the electrical potential of the first scanning signals transmitted on the first scanning layer GA11 and the second scanning layer GA12 is instantly pulled up, and then restored to the target potential. In this process, the parasitic capacitance formed between the first scanning lines GA1 and the nodes N1, as well as the gate-source capacitance Cgs of the compensation transistors T2, release electrical charges to the nodes N1, resulting in a potential difference at the nodes N1, so that the display substrate has a brightness difference between the first sub-region 1011 and the second sub-region 1012.

On the other hand: when the data signal transmitted by the data line DA undergoes a large jump, at the moment when the second scanning line GA2 controls the data writing transistor T4 to turn on, under the coupling effect of the N1 node, the N2 node, and the N3 node, the electrical potential of the first scanning signal transmitted on the first scanning layer GA11 and the second scanning layer GA12 is pulled up, and for different jumps of the data signal, the electrical potential is pulled up by different magnitudes. After the second scanning line GA2 controls the data writing transistor T4 to turn off, the first scanning signal transmitted on the first scanning layer GA11 and the second scanning layer GA12 is restored to the target potential. In this process, the parasitic capacitance formed between the first scanning lines GA1 and the nodes N1, as well as the gate-source capacitance Cgs of the compensation transistors T2, release the electrical charges to the nodes N1, resulting in a potential difference at the nodes N1, and eventually a crosstalk phenomenon occurs.

Therefore, when the display products with the foregoing structure are compatible with GOA single-sided driving technology and LTPO technology, there are problems such as abnormal display and Hole Mura.

Referring to FIGS. 4, 6 and 7, an embodiment of the present disclosure provides a display substrate, including: a display region 10 and a peripheral region 20 located at a periphery of the display region 10; the peripheral region 20 including a first bezel region 201 and a second bezel region 202 arranged opposite to each other along a first direction; the display region 10 is located between the first bezel region 201 and the second bezel region 202, the display region 10 including a first display region 101 and a second display region 102, the first display region 101 including a first sub-region 1011 and a second sub-region 1012, at least a part of the second sub-region 1012 is located in the same row as the second display region 102 along the first direction, and the first sub-region 1011 and the second display region 102 are located in different rows along the first direction.

The display substrate further includes: a plurality of first scanning driving units GA1 GOA and a plurality of first scanning lines GA1; the first scanning driving units GA1 GOA are located in the first bezel region 201; each of the first scanning lines GA1 includes a first scanning layer GA11 and a second scanning layer GA12.

The plurality of first scanning lines GA1 include a plurality of first target scanning lines, at least a part of each of the first target scanning lines is located in the second sub-region 1012; in the first target scanning line, a first end of the first scanning layer GA11 is coupled to a first end of the second scanning layer GA12, and is coupled to a corresponding first scanning driving unit GA1 GOA of the first scanning driving units GA1 GOA, a second end of the first scanning layer GA11 is coupled to a second end of the second scanning layer GA12, the first ends are close to the first bezel region 201, and the second ends are close to the second bezel region 202.

Exemplarily, the first display region 101 surrounds the second display region 102.

Exemplarily, the second sub-region 1012 includes a region for laying out sub-pixels and also includes a region for laying out a circling wire portion.

Exemplarily, a part of the second sub-region 1012 is located in the same row as the second display region 102 along the first direction. Another part of the second sub-region 1012 and the second display region 102 are arranged along the second direction. Said another part of the second sub-region 1012 is arranged on both sides of the second display region 102 along the second direction.

Exemplarily, in some embodiments, the display substrate includes a plurality of sub-pixels, each of the sub-pixels includes a sub-pixel driving circuit, the sub-pixel driving circuit includes a driving transistor T3 and a compensation transistor T2, a gate electrode of the compensation transistor T2 is coupled to the first scanning layer GA11 and the second scanning layer GA12 in the corresponding first scanning line GA1, a first electrode of the compensation transistor T2 is coupled to the second electrode of the driving transistor T3, and a second electrode of the compensation transistor T2 is coupled to the gate electrode of the driving transistor T3.

According to the specific structure of the foregoing display substrate, in the display substrate provided in the embodiments of the present disclosure, the plurality of first scanning lines GA1 including a plurality of first target scanning lines are provided, at least a part of each of the first target scanning lines is located in the second sub-region 1012, and in each of the first target scanning lines, the first end of the first scanning layer GA11 is coupled to the first end of the second scanning layer GA12 and is coupled to a corresponding first scanning driving unit GA1 GOA of the first scanning driving units GA1 GOA, the second end of the first scanning layer GA11 and the second end of the second scanning layer GA12 are coupled, the first ends are located in the first bezel region 201, and the second ends are located in the second bezel region 202.

The above arrangement enables that, for the first target scanning line in the second sub-region 1012, the first end of the first scanning layer GA11 and the first end of the second scanning layer GA12 are coupled in the first bezel region 201, and the second end of the first scanning layer GA11 and the second end of the second scanning layer GA12 are coupled in the second bezel region 202. In this way, the differential charges accumulated by the first target scanning lines due to the different structures can be better averaged, thereby effectively reducing the magnitude by which the first scanning signal transmitted by the first target scanning line is pulled up due to the change of the second scanning signal transmitted by the second scanning line GA2, realizing the rapid release of charges, and achieving the purpose of quickly restoring the first scanning signal transmitted by the first target scanning line to the target potential, thereby reducing the impact on the nodes N1, improving the crosstalk phenomenon, and mitigating the brightness difference between the first sub-region 1011 and the second sub-region 1012 of the display substrate.

Therefore, when the display substrate of the foregoing structure is compatible with GOA single-sided driving technology and LTPO technology, there are problems such as abnormal display and Hole Mura.

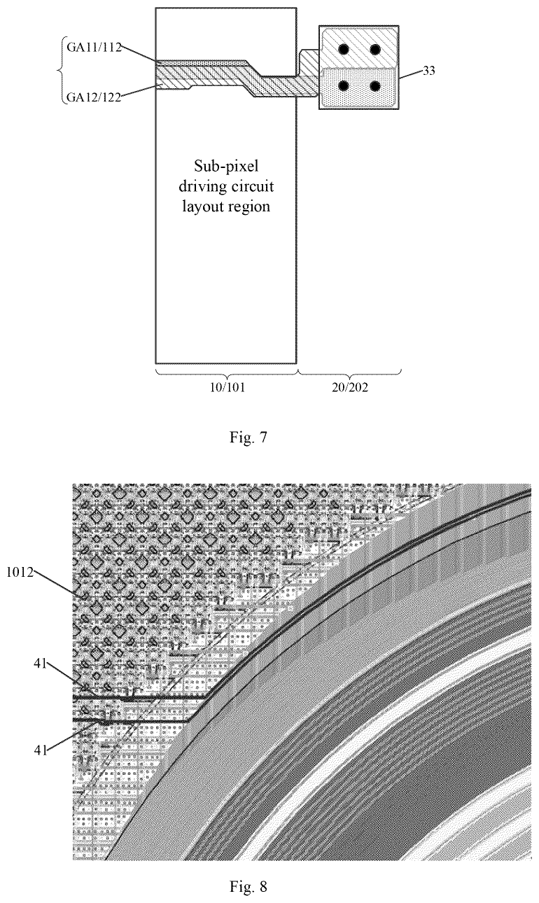

As shown in FIGS. 4 and 7, in some embodiments, the plurality of first scanning lines GA1 include a plurality of second target scanning lines, at least a part of each of the second target scanning lines is located in the first sub-region 1011; and in each of the second target scanning lines, a first end of the first scanning layer GA11 is coupled to the first end of the second scanning layer GA12, and is coupled to a corresponding first scanning driving unit of the first scanning driving units GA1 GOA, a second end of the first scanning layer GA11 is coupled to the second end of the second scanning layer GA12, the first ends are located in the first bezel region 201, and the second ends are located in the second bezel region 202.

Exemplarily, the first target scanning lines are located in the first sub-region 1011, the second target scanning lines are located in the second sub-region 1012, and the first target scanning line does not include a circling wire portion.

The above arrangement enables that, for the second target scanning line located in the first sub-region 1011, the first end of the first scanning layer GA11 and the first end of the second scanning layer GA12 are coupled in the first bezel region 201, and the second end of the first scanning layer GA11 and the second end of the second scanning layer GA12 are coupled in the second bezel region 202. In this way, the charges accumulated on the second target scanning line can be better averaged, thereby effectively reducing the magnitude by which the first scanning signal transmitted by the second target scanning line is pulled up due to the influence of the change of the second scanning signal, realizing the rapid release of charges, and achieving the purpose of quickly restoring the first scanning signal transmitted by the first target scanning line to the target potential, thereby reducing the impact on the nodes N1, improving the crosstalk phenomenon, and mitigating the brightness difference between the first sub-region 1011 and the second sub-region 1012 of the display substrate.

As shown in FIGS. 8 to 11, in some embodiments, in the first target scanning line, the first scanning layer GA11 includes a first scanning pattern 111 and a second scanning pattern 112, and the second scanning layer GA12 includes a third scanning pattern 121 and a fourth scanning pattern 122; the second display region 102 is located between the first scanning pattern 111 and the second scanning pattern 112, and the second display region 102 is located between the third scanning pattern 121 and the fourth scanning pattern 122.

The first end of the first scanning pattern 111 is the first end of the first scanning layer GA11, the second end of the second scanning pattern 112 is the second end of the first scanning layer GA11, the first end of the third scanning pattern 121 is the first end of the second scanning layer GA12, and the second end of the fourth scanning pattern 122 is the second end of the second scanning layer GA12; the second end of the first scanning pattern 111 is coupled to the second end of the third scanning pattern 121, and the first end of the second scanning pattern 112 is coupled to the first end of the fourth scanning pattern 122.

Exemplarily, the first target scanning line further includes a circling wire portion 41, the circling wire portion is located in the second sub-region 1012, and at least a part of the circling wire portion 41 is arranged around the second display region 102; the circling wire portion 41 is coupled to the second end of the first scanning pattern 111, the first end of the second scanning pattern 112, the second end of the third scanning pattern 121 and the first end of the fourth scanning pattern 122.

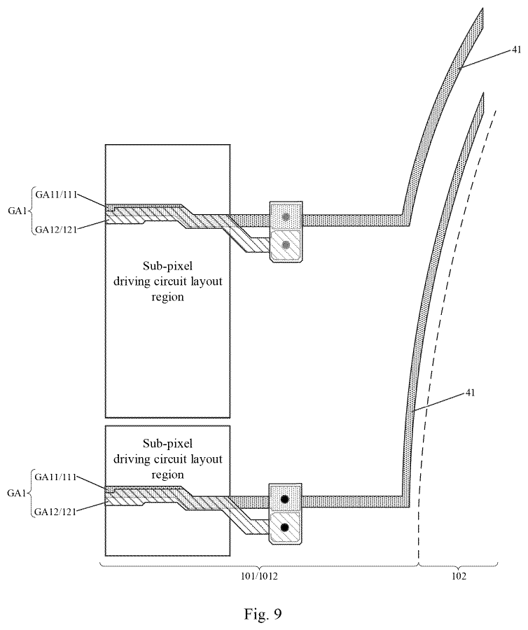

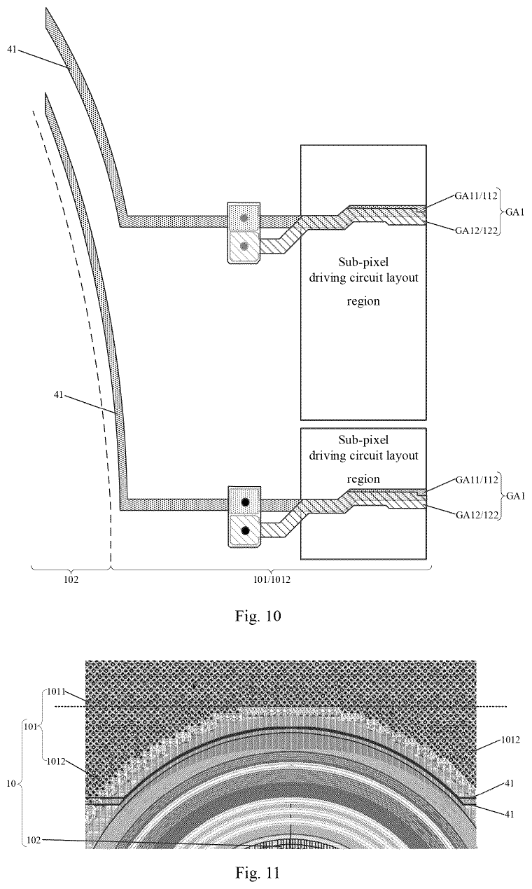

Exemplarily, as shown in FIG. 9 and FIG. 10, the circling wire portions 41 coupled to adjacent first scanning patterns 111 are independent of each other; or, as shown in FIG. 5, adjacent first scanning patterns 111 are coupled to a same circling wire portion 40.

By arranging the circling wire portions coupled to the adjacent first scanning patterns 111 to be independent of each other, the structural difference between the first target scanning line and the second target scanning line can be reduced, thereby reducing the difference in charges accumulated on the first target scanning line and the second target scanning line, and further mitigating the brightness difference between the first sub-region 1011 and the second sub-region 1012 of the display substrate.

As shown in FIG. 4, in some embodiments, the plurality of first scanning lines GA1 are divided into a plurality of scanning groups, and each of the scanning groups includes two adjacent first scanning lines GA1; the display substrate includes a plurality of first adapter portions 31, and each of the first adapter portions 31 is coupled to the first ends of the first scanning layers GA11 and the first ends of the second scanning layers GA12 in the corresponding scanning group, and a corresponding first scanning driving unit GA1 GOA.

The above arrangement can reduce the number of the first scanning driving units GA1 GOA required, which is beneficial to the development of a narrow bezel of the display substrate.

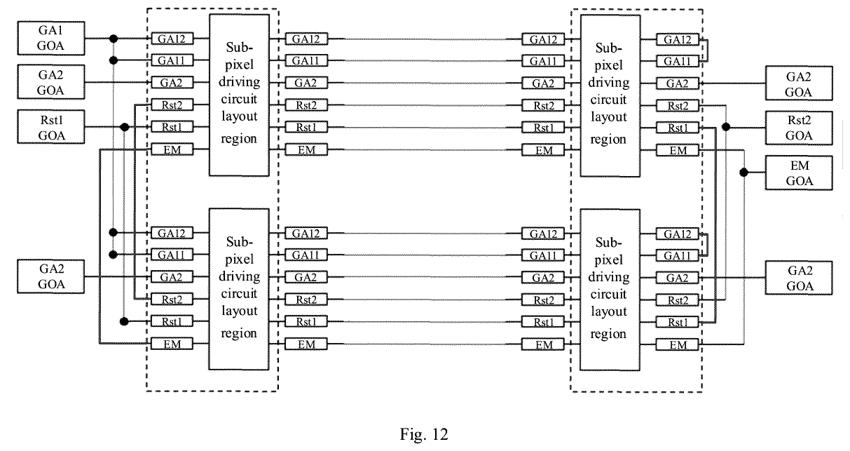

As shown in FIG. 7 and FIG. 12, in some embodiments, the display substrate includes a plurality of third adapter portions 33; each of the third adapter portions 33 is coupled to the second end of the first scanning layer GA11 and the second end of the second scanning layer GA12 in the corresponding first scanning line GA1.

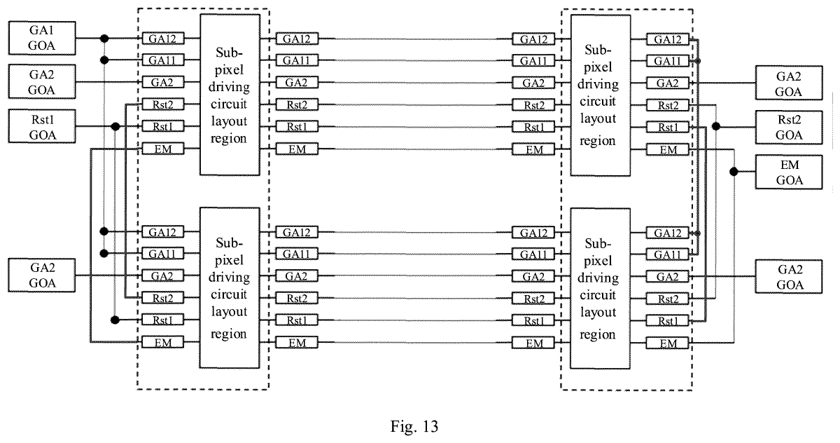

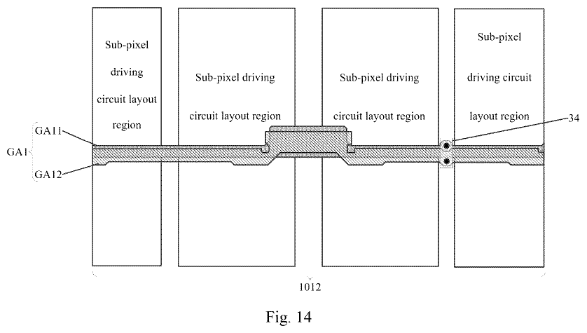

As shown in FIG. 13, exemplarily, the third adapter portions 33 coupled to the first scanning lines GA1 in each of the scanning groups are coupled to each other.

The above arrangement can better average the charges accumulated on the first target scanning line, thereby effectively reducing the magnitude by which the first scanning signal transmitted by the second target scanning line is pulled up due to the influence of the change of the second scanning signal, realizing the rapid release of charges, and achieving the purpose of quickly restoring the first scanning signal transmitted by the first target scanning line to the target potential, thereby reducing the impact on the nodes N1, improving the crosstalk phenomenon, and mitigating the brightness difference between the first sub-region 1011 and the second sub-region 1012 of the display substrate.

In some embodiments, the greater a length of the circling wire portion is, the less a load of the third adapter portion 33 is set to be.

The above arrangement can achieve differentiated compensation, which is beneficial to improvement of the brightness uniformity of the display substrate.

In some embodiments, the display substrate includes a first gate metal layer, a second gate metal layer, a third gate metal layer, a first source-drain metal layer, and a second source-drain metal layer, which are sequentially stacked on the base substrate of the display substrate in a direction away from the base substrate.

At least a part of the first adapter portion 31 is arranged in the same layer and is made of the same material as the first gate metal layer, the second gate metal layer, the third gate metal layer, the first source-drain metal layer or the second source-drain metal layer.

At least a part of the third adapter portion 33 is arranged in the same layer and is made of the same material as the first gate metal layer, the second gate metal layer, the first source-drain metal layer or the second source-drain metal layer.

The above arrangement enables the first adapter portion 31 to be formed in the same patterning process as that of the first gate metal layer, the second gate metal layer, the third gate metal layer, the first source-drain metal layer or the second source-drain metal layer.

The above arrangement enables the third adapter portion 33 to be formed in the same patterning process as that of the first gate metal layer, the second gate metal layer, the first source-drain metal layer or the second source-drain metal layer.

In some embodiments, in the same first scanning line GA1, an orthographic projection of the first end of the first scanning layer GA11 on the base substrate of the display substrate has an overlapping region with an orthographic projection of the first end of the second scanning layer GA12 on the base substrate, and the first end of the first scanning layer GA11 and the first end of the second scanning layer GA12 are coupled in the overlapping region through a via hole; and/or,
in the same first scanning line GA1, an orthographic projection of the second end of the first scanning layer GA11 on the base substrate has an overlapping region with an orthographic projection of the second end of the second scanning layer GA12 on the base substrate, and the first end of the first scanning layer GA11 and the first end of the second scanning layer GA12 are coupled in the overlapping region through a via hole.

The above arrangement is beneficial to narrowing the bezel width of the display substrate.

In some embodiments, the display substrate includes a first gate metal layer, a second gate metal layer, a third gate metal layer, a first source-drain metal layer, and a second source-drain metal layer, which are sequentially stacked on the base substrate of the display substrate in a direction away from the base substrate;
the circling wire portion is arranged in the same layer and is made of the same material as the first gate metal layer, the second gate metal layer, the third gate metal layer, the first source-drain metal layer or the second source-drain metal layer.

With the circling wire portion being arranged in the same layer and being made of the same material as the first gate metal layer, the second gate metal layer, the third gate metal layer, the first source-drain metal layer or the second source-drain metal layer, the circling wire portion can be formed in the same patterning process as that of the first gate metal layer, the second gate metal layer, the third gate metal layer, the first source-drain metal layer or the second source-drain metal layer.

In some embodiments, the circling wire portions included in two adjacent first target scanning lines are arranged in the same layer or in different layers.

The above arrangement of the circling wire portions in the same layer is conducive to simplifying the manufacturing process. The above arrangement of the circling wire portions in different layers can not only reduce the short-circuit risk of adjacent circling wire portions, but also overlap the orthographic projections of adjacent circling wire portions on the base substrate to achieve high-resolution display.

In some embodiments, the display substrate further includes a plurality of second scanning lines GA2, a plurality of light-emitting control signal lines EM, a plurality of first reset signal lines Rst1, and a plurality of second reset signal lines Rst2;
an orthographic projection of the circling wire portion on the base substrate of the display substrate at least partially overlaps with an orthographic projection of at least one signal line among the second scanning lines GA2, the light emitting control signal lines EM, the first reset signal lines Rst1 and the second reset signal lines Rst2 on the base substrate; the at least one signal line and the circling wire portion are arranged in different layers.

Exemplarily, in the second sub-region 1012, the second scanning line GA2, the light-emitting control signal line EM, the first reset signal line Rst1, and the second reset signal line Rst2 all have a circling wire portion.

The above arrangement can reduce the risk of short-circuit in the circling wire portion and can also achieve high-resolution display.

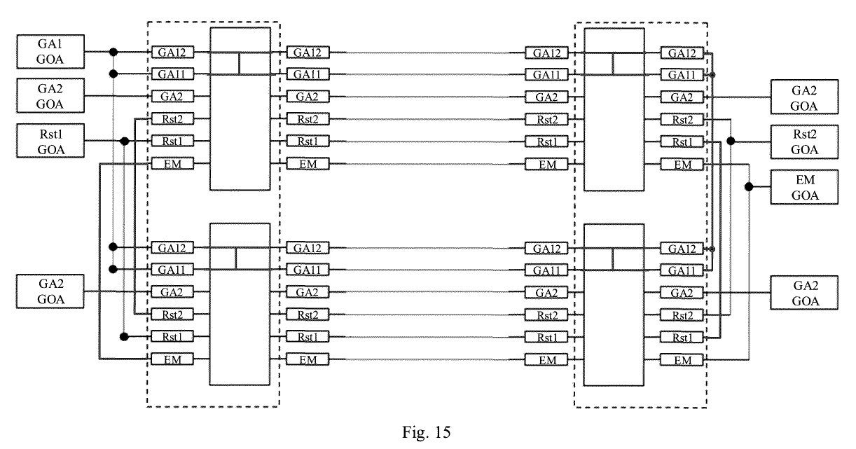

As shown in FIG. 14 and FIG. 15, in some embodiments, the display substrate includes a plurality of sub-pixels, and each of the sub-pixels includes a sub-pixel driving circuit; and
the first scanning layer GA11 and the second scanning layer GA12 of the same first target scanning line are coupled through at least one fourth adapter portion 34.

Exemplarily, the fourth adapter portion 34 is arranged in the same layer and is made of the same material as the first source-drain metal layer, but is not limited thereto.

Exemplarily, at least a part of the fourth adapter portion 34 is located within a layout region of the sub-pixel driving circuit, or at least a part of the fourth adapter portion 34 is located between layout regions of adjacent sub-pixel driving circuits.

Exemplarily, the first scanning line GA1 includes at least two fourth adapter portions 34, at least one of the fourth adapter portions 34 is located between the first bezel region 201 and the second display region 102, and at least one of the fourth adapter portions 34 is located between the second bezel region 202 and the second display region 102.

The above arrangement can better average the differential charges accumulated by the first target scanning lines, thereby effectively reducing the magnitude by which the first scanning signal transmitted by the first target scanning line is pulled up due to the change of the second scanning signal transmitted by the second scanning line GA2, and realizing the rapid release of charges, so as to achieve the purpose of quickly restoring the first scanning signal transmitted by the first target scanning line to the target potential, thereby reducing the impact on the nodes N1, improving the crosstalk phenomenon, and mitigating the brightness difference between the first sub-region 1011 and the second sub-region 1012 of the display substrate.

An embodiment of the present disclosure further provides a display device, including the display substrate according to the above embodiments.

It should be noted that the display device can be any product or component with a display function, such as a television, a monitor, a digital photo frame, a mobile phone, a tablet computer, wherein the display device also includes a flexible circuit board, a printed circuit board and a backplane, etc.

The display substrate according to the above embodiments can better average the differential charges accumulated by the first target scanning lines, thereby effectively reducing the magnitude by which the first scanning signal transmitted by the first target scanning line is pulled up due to the influence of the change of the second scanning signal transmitted by the second scanning line, and realizing the rapid release of charges, so as to achieve the purpose of quickly restoring the first scanning signal transmitted by the first target scanning line to the target potential, thereby reducing the impact on the nodes N1, improving the crosstalk phenomenon, and mitigating the brightness difference between the first sub-region and the second sub-region of the display substrate.

The display device according to the embodiment of the present disclosure also has the above beneficial effects when including the above display substrate, which will not be described in detail here.

It should be noted that the signal line extends along the X direction means that the signal line includes a main portion and a secondary portion connected to the main portion, the main portion is a line, a line segment or a strip-shaped body, the main portion extends along the X direction, and the length of the main portion extending along the X direction is greater than the length of the secondary portion extending along other directions.

It should be noted that the layout region occupied by each sub-pixel driving circuit may be a region that can accommodate the sub-pixel driving circuit. Exemplarily, the region may be a rectangular region, but is not limited thereto.

It should be noted that the “same layer” in the embodiments of the present disclosure may refer to film layers on the same structural layer. Or, for example, film layers on the same layer may be a layer structure formed by forming film layers for a specific pattern with the same film forming process, and then patterning the film layers with the same mask through a single patterning process. Depending on the specific pattern, a single patterning process may include multiple exposure, development or etching processes, and the specific pattern in the formed layer structure may be continuous or discontinuous. These specific patterns may also be at different heights or have different thicknesses.

In the various method embodiments of the present disclosure, the serial numbers of the steps are not intended to limit the sequence of the steps. For a person of ordinary skill in the art, without the exercise of inventive labor, variations in the order of the steps also fall within the scope of this disclosure.

It should be noted that the various embodiments in this specification are described in a progressive manner, and for description of same or similar parts, references may be made to another embodiment among these embodiments. Each embodiment focuses on the aspects that different from other embodiments. Particularly, for method embodiments, since they are fundamentally similar to product embodiments, they are described more briefly, and for relevant details, reference can be made to the description of the product embodiments.

Unless otherwise defined, the technical or scientific terms used in this disclosure shall have the ordinary meaning understood by a person of ordinary skill in the art. The terms “first”, “second” and similar expressions used in this disclosure do not indicate any order, number or importance, but only to distinguish the different components. The terms such as “including” or “containing” mean that the element or object preceding the word includes the element or object listed after the word and its equivalents, and does not exclude other elements or objects. Terms such as “connection”, “coupling” or “attachment” are not limited to physical or mechanical connections, but may include electrical connections, whether direct or indirect. Expressions “Up”, “Down”, “Left”, “Right”, etc., are only used to indicate the relative positional relationship, and when the absolute position of the object being described changes, the relative positional relationship may also change accordingly.

It can be understood that when elements such as layer, film, area, or substrate are referred to as “on” or “under” another element, the element may be “directly” “on” or “under” another element, or there may be intermediate elements present.

In the description of the above embodiments, specific features, structures, materials, or characters may be combined in an appropriate manner in any one or more embodiments or examples.

The foregoing is only specific embodiments of the present disclosure, but the scope of this disclosure is not limited to this. Any changes or substitutions that a person of ordinary skill in the art can easily think of within the scope of the technology disclosed in this disclosure shall fall within the scope of this disclosure. Therefore, the scope of this disclosure shall be defined by the scope of the claims.

1. A display substrate, comprising: a display region and a peripheral region located at a periphery of the display region; wherein the peripheral region comprises a first bezel region and a second bezel region arranged opposite to each other along a first direction; the display region is located between the first bezel region and the second bezel region, the display region comprises a first display region and a second display region, the first display region comprises a first sub-region and a second sub-region, at least a part of the second sub-region is located in a same row as the second display region along the first direction, and the first sub-region and the second display region are located in different rows along the first direction;
the display substrate further comprising: a plurality of first scanning driving units and a plurality of first scanning lines; wherein the first scanning driving units are located in the first bezel region; the first scanning lines comprise a first scanning layer and a second scanning layer;
the plurality of first scanning lines comprising a plurality of first target scanning lines, at least a part of each of the first target scanning lines is located in the second sub-region, and in each of the first target scanning lines, a first end of the first scanning layer is coupled to a first end of the second scanning layer, and is coupled to a corresponding first scanning driving unit of the first scanning driving units, a second end of the first scanning layer is coupled to a second end of the second scanning layer, the first ends are located in the first bezel region, and the second ends are located in the second bezel region.

2. The display substrate according to claim 1, wherein the plurality of first scanning lines comprise a plurality of second target scanning lines, at least a part of each of the second target scanning lines is located in the first sub-region, and in each of the second target scanning lines, a first end of the first scanning layer is coupled to a first end of the second scanning layer, and is coupled to a corresponding first scanning driving unit of the first scanning driving units, a second end of the first scanning layer is coupled to a second end of the second scanning layer, the first ends are located in the first bezel region, and the second ends are located in the second bezel region.

3. The display substrate according to claim 1, wherein in each of the first target scanning lines, the first scanning layer comprises a first scanning pattern and a second scanning pattern, and the second scanning layer comprises a third scanning pattern and a fourth scanning pattern; the second display region is located between the first scanning pattern and the second scanning pattern, and the second display region is located between the third scanning pattern and the fourth scanning pattern;
a first end of the first scanning pattern is the first end of the first scanning layer, a second end of the second scanning pattern is the second end of the first scanning layer, a first end of the third scanning pattern is the first end of the second scanning layer, and a second end of the fourth scanning pattern is the second end of the second scanning layer; a second end of the first scanning pattern is coupled to a second end of the third scanning pattern, and a first end of the second scanning pattern is coupled to a first end of the fourth scanning pattern.

4. The display substrate according to claim 3, wherein the first target scanning line further comprises a circling wire portion, the circling wire portion is located in the second sub-region, and at least a part of the circling wire portion is arranged around the second display region; the circling wire portion is coupled to the second end of the first scanning pattern, the first end of the second scanning pattern, the second end of the third scanning pattern and the first end of the fourth scanning pattern.

5. The display substrate according to claim 4, wherein the circling wire portions coupled to the adjacent first scanning patterns are independent of each other; or, the adjacent first scanning patterns are coupled to the same circling wire portion.

6. The display substrate according to claim 4, wherein the plurality of first scanning lines are divided into a plurality of scanning groups, each of the scanning groups comprising two adjacent first scanning lines of the plurality of first scanning lines; the display substrate comprises a plurality of first adapter portions, each of the first adapter portions is coupled to the first ends of the first scanning layers and the first ends of the second scanning layers in the corresponding scanning group, and a corresponding first scanning driving unit of the first scanning driving units.

7. The display substrate according to claim 6, wherein the display substrate comprises a plurality of third adapter portions; each of the third adapter portions is coupled to the second end of the first scanning layer and the second end of the second scanning layer in a corresponding first scanning line of the first scanning lines.

8. The display substrate according to claim 7, wherein the third adapter portions coupled to the first scanning lines in each of the scanning groups are coupled to each other.

9. The display substrate according to claim 7, wherein the display substrate comprises a first gate metal layer, a second gate metal layer, a third gate metal layer, a first source-drain metal layer, and a second source-drain metal layer that are sequentially stacked on a base substrate of the display substrate in a direction away from the base substrate;
at least a part of each of the first adapter portions is arranged in the same layer and is made of the same material as the first gate metal layer, the second gate metal layer, the third gate metal layer, the first source-drain metal layer or the second source-drain metal layer;
at least a part of each of the third adapter portions is arranged in the same layer and is made of the same material as the first gate metal layer, the second gate metal layer, the first source-drain metal layer or the second source-drain metal layer.

10. The display substrate according to claim 7, wherein the greater a length of the circling wire portion is, the less a load of the third adapter portion is set to be.

11. The display substrate according to claim 1, wherein in the same first scanning line, an orthographic projection of the first end of the first scanning layer on a base substrate of the display substrate has an overlapping region with an orthographic projection of the first end of the second scanning layer on the base substrate, and the first end of the first scanning layer and the first end of the second scanning layer are coupled through a via hole in the overlapping region; and/or,
in the same first scanning line, an orthographic projection of the second end of the first scanning layer on the base substrate has an overlapping region with an orthographic projection of the second end of the second scanning layer on the base substrate, and the second end of the first scanning layer and the second end of the second scanning layer are coupled through a via hole in the overlapping region.

12. The display substrate according to claim 1, wherein the display substrate comprises a plurality of sub-pixels, each of the sub-pixels comprises a sub-pixel driving circuit, the sub-pixel driving circuit comprises a driving transistor and a compensation transistor, a gate electrode of the compensation transistor is coupled to the first scanning layer and the second scanning layer in a corresponding first scanning line of the first scanning lines, a first electrode of the compensation transistor is coupled to a second electrode of the driving transistor, and a second electrode of the compensation transistor is coupled to a gate electrode of the driving transistor.

13. The display substrate according to claim 4, wherein the display substrate comprises a first gate metal layer, a second gate metal layer, a third gate metal layer, a first source-drain metal layer, and a second source-drain metal layer that are sequentially stacked on a base substrate of the display substrate in a direction away from the base substrate;
the circling wire portion is arranged in the same layer and is made of the same material as the first gate metal layer, the second gate metal layer, the third gate metal layer, the first source-drain metal layer or the second source-drain metal layer.

14. The display substrate according to claim 4, wherein the circling wire portions comprised in two adjacent first target scanning lines of the first target scanning lines are arranged in the same layer or are arranged in different layers.

15. The display substrate according to claim 4, wherein the display substrate further comprises a plurality of second scanning lines, a plurality of light-emitting control signal lines, a plurality of first reset signal lines and a plurality of second reset signal lines;
an orthographic projection of the circling wire portion on a base substrate of the display substrate at least partially overlaps with an orthographic projection of at least one signal line among the second scanning lines, the light-emitting control signal lines, the first reset signal lines and the second reset signal lines on the base substrate; the at least one signal line and the circling wire portion are arranged in different layers.

16. The display substrate according to claim 1, wherein the display substrate comprises a plurality of sub-pixels, and each of the sub-pixels comprises a sub-pixel driving circuit, and
the first scanning layer and the second scanning layer of the same first target scanning line are coupled through at least one fourth adapter portion.

17. The display substrate according to claim 16, wherein at least a part of the fourth adapter portion is located in a layout region of the sub-pixel driving circuit, or, at least a part of the fourth adapter portion is located between layout regions of adjacent sub-pixel driving circuits.

18. The display substrate according to claim 16, wherein
each of the first scanning lines comprises at least two fourth adapter portions, at least one of the fourth adapter portions is located between the first bezel region and the second display region, and at least one of the fourth adapter portions is located between the second bezel region and the second display region.

19. A display device, comprising a display substrate, the display substrate comprising: a display region and a peripheral region located at a periphery of the display region; wherein the peripheral region comprises a first bezel region and a second bezel region arranged opposite to each other along a first direction; the display region is located between the first bezel region and the second bezel region, the display region comprises a first display region and a second display region, the first display region comprises a first sub-region and a second sub-region, at least a part of the second sub-region is located in a same row as the second display region along the first direction, and the first sub-region and the second display region are located in different rows along the first direction;
the display substrate further comprising: a plurality of first scanning driving units and a plurality of first scanning lines; wherein the first scanning driving units are located in the first bezel region; the first scanning lines comprise a first scanning layer and a second scanning layer;
the plurality of first scanning lines comprising a plurality of first target scanning lines, at least a part of each of the first target scanning lines is located in the second sub-region, and in each of the first target scanning lines, a first end of the first scanning layer is coupled to a first end of the second scanning layer, and is coupled to a corresponding first scanning driving unit of the first scanning driving units, a second end of the first scanning layer is coupled to a second end of the second scanning layer, the first ends are located in the first bezel region, and the second ends are located in the second bezel region.

20. The display device according to claim 19, wherein the plurality of first scanning lines comprise a plurality of second target scanning lines, at least a part of each of the second target scanning lines is located in the first sub-region, and in each of the second target scanning lines, a first end of the first scanning layer is coupled to a first end of the second scanning layer, and is coupled to a corresponding first scanning driving unit of the first scanning driving units, a second end of the first scanning layer is coupled to a second end of the second scanning layer, the first ends are located in the first bezel region, and the second ends are located in the second bezel region.
